(19) United States
(12) Patent Application Publication
(10) Pub. No.: US 2008/0189059 A1
(43) Pub. Date: Aug. 7, 2008

(54) System for inspection and separation of defective RFID tags in batch conversion of RFID tag to RFID label

(76) Inventors: Alex Poh Teck Choong, Singapore (SG); Yew Sang Chin, Singapore (SG)

Correspondence Address: Nields & Lemack, 176 E. Main Street, Suite #5, Westboro, MA, 01581, US

(21) Appl. No.: 11/702,880

(22) Filed: Feb. 6, 2007

(51) Int. Cl. G01R 15/00

(52) U.S. Cl. 702/57

(57) ABSTRACT

A RFID detection and separation device for a RFID Conversion system incorporating a microcontroller, a liner unwinding station, a RFID reel unwinding station, a RFID feeding station, a liner feeding station. The microcontroller controls the movement of an inlay reel of RFID tags from the RFID reel unwinding station into the RFID feeding station, said microcontroller also controlling the movement of a reel of liner mounted on a Liner Unwinding station, through a liner feeding station, for the separation of the RFID tags from the inlay reel for embedding onto the liner to produce RFID labels.

In its separation mode, a RFID tag is inspected and if found good, the RFID tag is separated by the RFID detection and separation device and dispensed onto a liner to form a RFID label. Upon detection of a defective RFID tag, the RFID detection and separation device goes into a non-separation mode, whereby the defective RFID tag goes past the RFID detection and separation device without separation from the inlay reel. As a result only good RFID labels are produced.

### TECHNICAL FIELD

The present invention is related to a device and method to inspect and reject defective RFID tags in the process of batch conversion of the RFID tag to RFID label whereby RFID tags are embedded into paper labels of varying sizes, in accordance to customer requirements.

### BACKGROUND ART

Radio Frequency Identification (RFID) uses a smart tag capable of transmitting data by radio. The basic RFID system consists of 3 components:
An antenna or coil
A transceiver (with decoder)
A transponder tag (called a RFID tag) electronically programmed with unique information

The basic feature of a RFID tag is to detect the interrogation field or transmission in order to affect a response for data transfer. The main components in a RFID tag circuitry essentially comprises of the following elements:
The antenna and radio frequency receiver and transmission circuit
Micro-processing circuit for control and data management purpose.
Memory, appropriate to data carrier and functionality needs.

There are basically 3 types of RFID transponders that are most widely used in the world. They are (a) contactless cards, (b) contactless tickets and (c) smart labels.

A smart RFID label has a transponder device with a programmable microchip and an antenna. Data can be read or written with a reader device, without a direct line of sight. Transponders embedded inside paper labels (“RFID labels”) assist businesses in product identification, control, tracking and security and are used in a wide variety of many applications.

Methods of manufacture of RFID labels are known. For example, U.S. Pat. No. 6,451,154 describes a high volume method of making RFID labels comprising: (a) providing a plurality of RFID inlets, each including a chip (and antenna), on a first web; (b) covering the RFID inlets with a second web to provide a composite web; (c) providing pressure sensitive adhesive on a portion of one of the webs that will be an exterior portion of a label once ultimately formed; (d) verifying the functionality of, or programming, the chips prior to formation of the composite web; and, (e) acting on the composite web so as to provide the composite web into labels having a top face, and a bottom face with pressure sensitive adhesive. Step (b) is practiced by laminating the first and second webs by passing them between laminating rolls without harming the RFID inlets by providing a recess in at least one of the laminating rolls in alignment with the RFID inlets. The method may further comprise (f) imaging variable indicia on the top face. High speed practice of the method is possible; that is (a)-(e) may be practiced at a rate of at least about 100 feet per minute (e.g. up to about 300 ft./min.) and also typically (f) is practiced after (e).

An alternative process of manufacturing RFID labels is to convert RFID tag to RFID labels in batches. Such a batch conversion process has been described in PCT/SG2004/000302 filed on 17 Sep. 2004 (Choong Alex et al). This batch conversion process offers flexibility since specific batches of labels, as requested by the customer can be produced. Examples are shipping labels related to say, one particular container or even a few containers for a specific shipment or shipping labels for one particular flight. Such a specific batch conversion of RFID tags to RFID labels is unlike the invention described in U.S. Pat. No. 6,451,154.

Irrespective of whether it is a production of a high volume RFID labels or production of a batch of RFID labels, there are always defective or non-working RFID tags in a reel (referred to as “RFID inlay reel”).

According to PCT/US2005/034523, the percentage of labels having defective inlays is currently about 1-20%.

Again irrespective of whether it is a high volume printing process or batch printing process, both types of processes face much lost time and incur additional costs in testing and identifying defective RFID tags in the inlays before these are shipped to the end user. Another difficulty faced during the conversion of RFID tags to RFID labels is to properly identify defective RFID tags by testing and identifying each RFID tag at a reasonable speed since the printing and conversion process is on going. The testing and identifying of defective RFID tags is also complicated by the close proximity of each of the RFID tags since these are spaced in close proximity to each other in the RFID inlay reel. The close proximity of the RFID tags causes the testing unit to elicit readings from not just the defective RFID tag but the adjacent RFID tags, as well.

A solution offered by, PCT/US2005/034523 (Avery Dennison Corporation) is to remove each defective label from the web and use an optical sensor to read a mark treating it as though the removed label is still present.

PCT/SG2004/00302 proposes a novel batch conversion process in which the RFID tags and label liner are fed together at one point to convert the RFID tags into RFID labels. Each RFID tag must be accurately embedded onto each paper label and then encoded and have the bar codes printed in the same process.

Detection and removal of defective RFID tags is also an issue with such a batch conversion process. If the defective RFID tags are not detected before conversion into RFID labels, the resulting RFID label would be defective. Such defective labels have to be removed, prior to be used. End users therefore incur time and manpower to check each RFID label to ensure these are in good working condition. The presence of defective RFID labels would mean the RFID label producer has to embed more RFID tags to produce more RFID labels to cover any shortfall of good RFID labels requested by an end user. The costs of checking each RFID label and separation of defective RFID label would be high since the detection is done after the RFID labels are produced. The costs would include removing defective RFID label from a single reel of RFID labels, the removal of the defective RFID label causing breakage in the reel of RFID labels. The associated costs would also include downtime since the removal of defective RFID labels would mean interrupted printing or coding of the RFID labels

It is therefore desirable for a defective RFID tag to be detected and removed prior to conversion to RFID label so that the final output of reel of RFID label consisting of all working RFID labels.

However, detection of a defective RFID tag prior to using the RFID tags in the batch conversion process is still not an acceptable solution. It is possible that a RFID tag be damaged during the set up of the batch conversion process. It is preferable that any damaged RIFD tag be detected just before being embedded onto the liner as the final output would possibly be almost 100 percent non-defective.

U.S. Pat. No. 6,593,853 (Barett Tony J et al) proposes a solution wherein defective RFID labels are marked for identification and a replacement RFID label printed to make up for the defective RFID label. U.S. application Ser. No. 10/635,418 (Keith Jusas et al) adopts a similar treatment towards defective RFID labels.

It is therefore desirable that only non-defective RFID tags be embedded onto the liner to produce the RFID labels. It is desirable that any defective RFID tag be detected and immediately removed during the RFID batch conversion process before the defective RFID tag is embedded onto the liner to produce the RFID label. It is highly desirable if the defective RFID tag can be removed from the on-going conversion process without interruption of the batch conversion process, thereby reducing any possibility of downtime.

This invention offer a solution to the problem of detecting and separating defective RFID tags during the process of batch conversion of RFID tags to RFID labels.

Furthermore, this invention offers a solution in providing RFID end users with all working RFID labels, for use without the requirement for checking whether such RFID labels are in working condition.

The subject invention will ensure lower costs of labor/man-hour, improved efficiency of production/conversion process and reduced wastage during tag-label conversion. More fundamentally, the invention would result in a significant reduction of the costs of RFID labels, since all RFID labels are in working condition upon shipping out.

### SUMMARY OF THE INVENTION

It is an object of the present invention to provide a device and method to detect and separate a defective RFID tag prior to embedding a batch of RFID tag onto a label liner in the conversion of RFID tags to RFID labels, thereby resulting in an output of RFID labels in good working condition.

A first object of the invention is a RFID detection and separation device for a RFID Conversion system, said RFID Conversion system having a microcontroller, a liner unwinding station, a RFID reel unwinding station, a RFID feeding station, a liner feeding station, said microcontroller controlling the movement of an inlay reel of RFID tags from the RFID reel unwinding station into the RFID feeding station, said microcontroller also controlling the movement of a reel of liner mounted on a Liner Unwinding station, through a liner feeding station, for the separation of the RFID tags from the inlay reel for embedding onto the liner to produce RFID labels, characterized in that in a separation mode, a RFID tag is inspected and if found good, the RFID tag is separated by the RFID detection and separation device and dispensed onto a liner to form a RFID label, and upon detection of a defective RFID tag, the RFID detection and separation device goes into a non separation mode, whereby the defective RFID tag passes the RFID detection and separation device without separation from the inlay reel.

Preferably the RFID detection and separation device for a RFID Conversion system consist of:
a RFID inspection unit; and
a RFID separator;
   wherein the RFID tag is accurately positioned for inspection by the RFID inspection unit, and if the RFID tag is found defective, the RFID separator is retracted, allowing said defective RFID tag to remain on the inlay reel to return to RFID Conversion System and if found good, the RFID separator is not retracted, thereby allowing the RFID tag to be embedded onto the liner, to form a RFID label.

A second object of the invention is a system comprising a RFID detection and separation device to detect and separate a defective RFID tag for a RFID Conversion system, the system having:
a RFID inspection unit;
a RFID separator; and
a RFID Positioning unit
   wherein the RFID Positioning Unit positions the RFID tag accurately with respect to the RFID inspection unit and RFID separator in the detection and separation of a RFID tag for embedding onto the liner to produce a RFID label and in the detection and non-separation of a defective RFID tag from the RFID inlay reel if a defective RFID tag is found.

Advantageously, the system having a RFID detection and separation device to detect a defective RFID tag for a RFID Conversion system, comprises:
a RFID inspection unit;
a RFID separator;
a RFID Positioning unit; and
a RFID Tensioning Unit
   wherein the RFID Tensioning unit maintains a constant tension in the RFID inlay reel to prevent reel breakage at high operation speed.

Preferably, the RFID Tensioning Unit consisting of a plurality of dancers and a pair of inlay reel brakes.

Alternatively, the RFID Tensioning Unit consists of a servomotor with torque control.

Alternatively, the RFID Tensioning Unit consists of a motor and clutch.

Preferably, after a defective RFID tag is detected by the RFID inspection unit, it moves on over the RFID separator, the inlay reel brakes closes on the inlay reel to stop the inlay reel from moving and at the same time the RFID separator is retracted, so that the RFID tag does not separate from the inlay reel to be embedded onto the liner to return to a winding station and thereafter said pair of inlay reel brakes opens, the inlay reel moves forward with another RFID tag to be inspected.

Preferably, the RFID Positioning unit for use with the system to detect and separate a defective RFID tag consist of a vision system which checks the position of the RFID tag to ensure it is accurately positioned with respect to the RFID separator so that the RFID tag can be read accurately by the RFID inspection unit after each dispensing cycle.

Advantageously, the RFID Positioning unit for use with the system to detect and separate a defective RFID consists of a vision system which checks and adjust the position of the RFID tag on the inlay reel so that only the RFID tag directly below the RFID inspection unit is inspected.

Alternatively, the RFID Positioning unit for use with the system to detect and separate a defective RFID consists of an imaging system which takes an image of the RFID tag, checks and adjust the position of the RFID tag on the inlay reel so that only the RFID tag directly below the RFID inspection unit is inspected.

Preferably, the RFID inspection unit of the RFID detection and separation device consists of a RFID reader to read the RFID tag.

Advantageously, the RFID inspection unit consists of the RFID reader mounted with an electronic shield to direct the electronic signals of the RFID reader onto the RFID tag immediately below the RFID inspection unit so as to only read this RFID tag.

Alternatively, the RFID inspection unit consists of the RFID reader mounted with a RFID signal deflector to direct the electronic signals of the RFID reader onto the RFID tag immediately below the RFID inspection unit so as to only read this RFID tag.

Alternatively, the RFID inspection unit consists of the RFID reader mounted with a RFID signal guide to guide the electronic signals of the RFID reader onto the RFID tag immediately below the RFID inspection unit so as to only read this RFID tag.

Preferably, the RFID separator of the RFID detection and separation device is positioned above the liner and in a separation mode is in an extended state so that as the RFID inlay reel with the RFID tags on it goes over the RFID separator, the RFID separator separates the RFID tags from the RFID inlay reel allowing the RFID tags to be dispensed onto the liner, thereby embedding the RFID tag onto the liner, to form RFID labels.

Preferably, the RFID separator for a RFID detection and separation device is positioned above the liner and upon detection of a defective RFID tag, the RFID detection and separation device goes into a non-separation mode whereby the microcontroller sends a signal to the RFID separator, causing it to retract and as the RFID separator is no longer in an extended state, the RFID inlay reel with the defective RFID tag on it round goes over the retracted RFID separator, the inlay reel forming a free loop, so that the defective RFID tag would not be dispensed onto the liner, and instead returned to the winding station.

More advantageously, upon detection by the RFID inspection unit of a defective RFID tag, the RFID detection and separation device goes into a non-separation mode, whereby the position of the defective RFID tag is recorded by the microcontroller, which continues to move the inlay reel with the defective RFID tag along until it reaches the edge of the RFID separator, the microcontroller sends a signal to a inlay reel brakes of the RFID Tensioning Unit so that it closes on the inlay reel and at the same time, the RFID separator retracts, and the RFID inlay forms a free loop around the retracted RFID separator, so that the RFID tag on the inlay reel is not dispensed onto the liner and instead returns to a winding station.

Preferably, the RFID separator is positioned above the liner so that after the defective RFID tag has been detected by the RFID inspection unit, and after the defective RFID tag has gone past the retracted RFID separator, the RFID detection and separation device goes back to its separation mode whereby the microcontroller sends a signal to the inlay reel brakes of the RFID Tensioning Unit to release the RFID inlay, and the RFID separator moves back to its normal extended position, and the RFID tags are moved forwards through the RFID detection and separation device to continue the RFID conversion process.

Preferably, the RFID separator for a RFID detection and separation device is a retractable knife edge.

Alternatively the RFID separator for a RFID detection and separation device is a retractable blade.

Preferably, the pair of inlay reel brakes of the RFID Tensioning Unit is in an opened position, when the RFID detection and separation device is in a separation mode, such that the RFID tags on the inlay reel are moved through the RFID inspection unit, and when a good RFID tag is detected by the RFID inspection unit, the inlay reel brakes remains open so that the inlay reel with the good RFID tag moves pass the RFID separator, to be dispensed onto the liner, to produce RFID labels.

Preferably the pair of inlay reel brakes of the RFID Tensioning Unit is in an opened position, when the RFID tags on the inlay reel are moved through the RFID inspection unit, and when a defective RFID tag is detected by the RFID inspection unit, the RFID detection and separation device goes into a non-separation mode, whereby the microcontroller closes the pair of inlay reel brakes together to stop movement of the inlay reel and at the same time, the microcontroller retracts the RFID separator, causing the RFID inlay to form a free loop around the retracted RFID separator, so that the RFID tag on the inlay reel is not dispensed onto the liner and instead returns to a winding station.

Advantageously the pair of inlay reel brakes of the RFID Tensioning Unit, after the defective RFID tag has gone past the retracted RFID separator, to the winding station, the RFID detection and separation device goes back to its separation mode, whereby the microcontroller sends a signal to the inlay reel brakes to open, the RFID inlay is then released, causing the next RFID tag on the inlay reel to moved through the RFID inspection unit, and the RFID separator moves back to its normal extended position, so that the RFID conversion process continues.

Preferably, the pair of inlay reel brakes of the RFID Tensioning Unit is a pair of clamping cylinders.

Alternatively, the pair of inlay reel brakes of the RFID Tensioning Unit is a pair of clamping discs.

A further object of the invention is a method to detect and separate defective RFID tags using a RFID detection and separation device and system for a RFID Batch conversion system, comprising the following steps:
Inspecting a RFID tag as it goes under the home sensing unit;
sending an electronic signal from a RFID reader to read the RFID tag;
identifying a defective RFID and sending a signal to the microcontroller, which continue to move the RFID inlay reel containing said defective RFID tag; until it reaches the RFID separator,
sending a signal to the clamp cylinder to stop movement of the RFID inlay reel, when the defective RFID tag goes over the RFID separator,
retracting the RFID separator so it is no longer in an extended state,
allowing the RFID inlay reel with the defective RFID tag on it to go over the retracted RFID separator, said RFID inlay reel forming a free loop, so that the defective RFID tag would not be dispensed onto the liner,
and instead returns to the winding station;
sending a signal to the clamping cylinder to release the RFID inlay reel,
extending the RFID separator so that it moves back to its normal extended position,
so that the next RFID tag is moved forward to the inspection unit to be inspected
   and so continuing the RFID Batch conversion process until the microcontroller detects either the end of the RFID inlay reel or liner is reached and after which the RFID Batch Conversion process is stopped.

Preferably, the method to detect and separate defective RFID tags includes the steps of inspecting a RFID tag as it goes under the home sensing unit, detecting a defective RFID tag, moving the RFID tag past the RFID separator which is then retracted, braking the forward movement of the inlay reel so as to form a free loop, releasing the inlay reel brakes so that the inlay reel can move the next RFID tag to be inspected, all of these steps being controlled by the microcontroller.

### BRIEF DESCRIPTION OF THE DRAWINGS

For a better understanding of the invention, its advantages, and the objects attained by its use, reference should now be made to the accompanying drawings. The accompanying drawings illustrate one or more embodiments of the invention and together with the description herein, serve to explain the workings and principles of the invention.

FIG. 1 is a diagram of a RFID Conversion system using the detection and separation device of this invention in the batch process to convert RFID tags to RFID labels.

FIG. 2 is a close up view of the detection and separation device.

FIG. 3 shows the dispensing process wherein a good RFID tag will be separated from the RFID inlay.

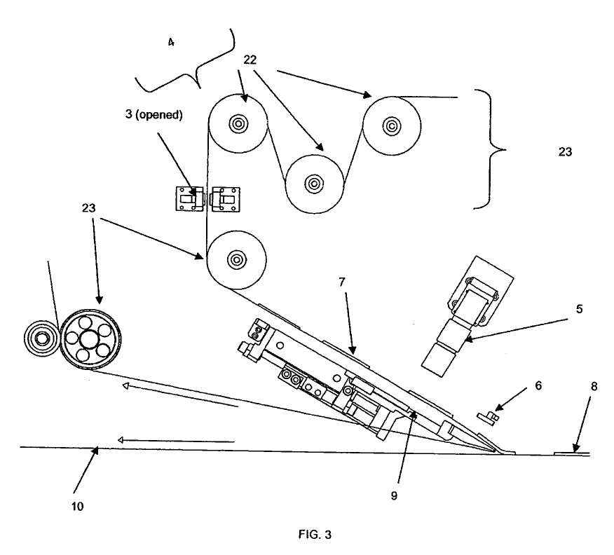

FIG. 4 shows the first step of the inspection and separation process in detecting a defective RFID tag.

FIG. 5 shows the second step of the inspection and separation process wherein a defective RFID tag is moved along back to the winding station, before the embedding process.

FIG. 6 shows the third step of inspection and separation process wherein the defective RFID tag is returned to the winding station upon rejection.

### BEST MODE FOR CARRYING OUT THE INVENTION

The preferred embodiment of the invention is described with reference to the attached drawings.

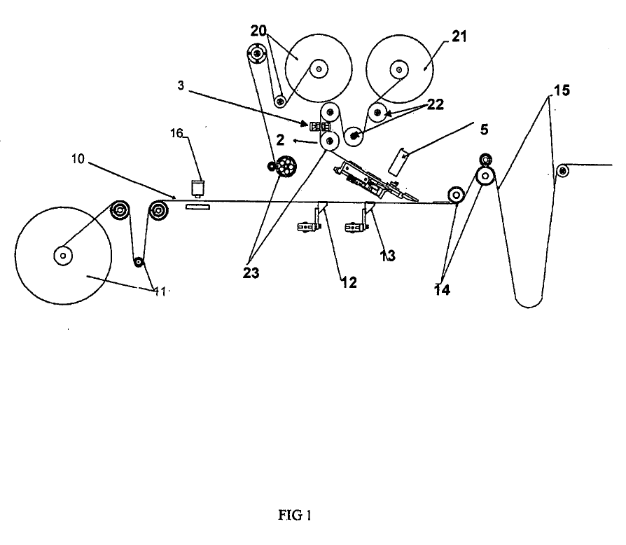

FIG. 1 is a diagram of a RFID Conversion system using the detection and separation device of this invention in the batch process to convert RFID tags to RFID labels.

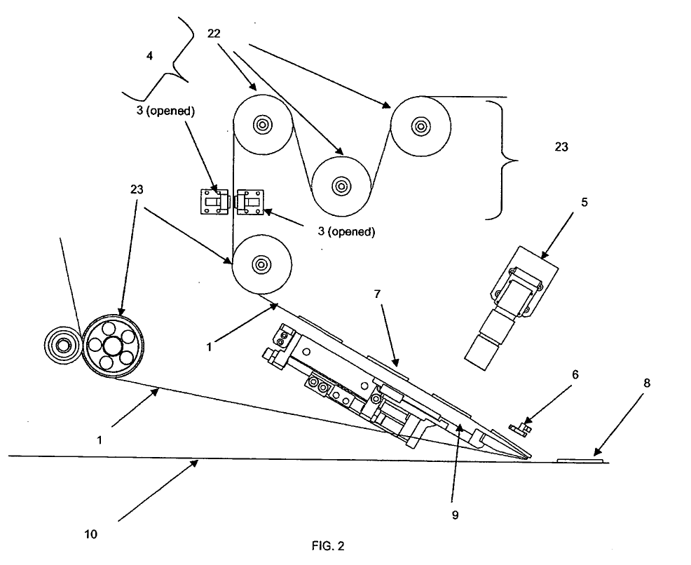

FIG. 2 is a close up view of the detection and separation device.

The RFID Conversion system has two reels mounted and fed into the system—an inlay reel 1 of RFID tags 7 and a reel of liner 10.

The RFID conversion system has the following components, as shown in FIG. 1. All components within the conversion system are controlled by a microcontroller (not shown), which receives information from each of these components and from each RFID tag 7 and which in turn relays signals to the other components, so that the entire conversion system runs smoothly.

RFID Reel Unwinding Station 21

The incoming RFID inlay reel 1 will be loaded onto this reel unwinding station 21. The holding shaft is connected to a motor, which unwinds the RFID inlay reel 1 to the RFID Tensioning Station 4.

RFID Reel Tensioning Station 4

The RFID Reel Tensioning Station 4 consists of the dancer unit 22 and a pair of inlay reel brakes 3. The dancer unit 22 provides a constant and correct tension to the unwound RFID inlay reel 1 during the dispensing process of the RFID tags 7. If the RFID inlay reel 1 is unwound at a too fast rate, the RFID inlay reel 1 would break, interrupting the entire process The inlay reel brakes 3 isolate the tension from the RFID separator 9 when the RFID separator 9 retracts during non-separation mode.

The dancer unit 22 is pneumatically powered with precision pressure control to provide a desirable tension to the RFID inlay reel 1 throughout the conversion system. The tension of the RFID inlay reel 1 is controlled so that it is just sufficient to enable dispensing at the separator 9. Excessive tension can increase the possibility of breakage when the RFID inlay reel 1 is fed through the RFID separator 9 at high speed.

The RFID Reel tensioning unit 4 is therefore a very essential component of the entire process of separating the RFID tags 7 from the RFID inlay reel 1 and embedding the same onto the liner 10 to form RFID labels 8.

RFID Feeding Station 23

This station consists of one set of feeding rollers 23 located after the separator 9. These rollers 23 are driven by one servo motor and the feed length can be programmed to suit different RFID tags 7 and different RFID labels 8.

RFID Inspection 6, Positioning 5 and Separation 9 Station

This station consists of a RFID Positioning unit 5, a RFID inspection unit 6 and a RFID separator 9, a close up view of which is given in FIG. 2.

RFID Positioning Unit 5

The RFID Positioning unit 5 utilises a vision system to check the position of the RFID tag 7 and it ensures that a RFID tag 7 is always accurately positioned with respect to the RFID separator 9 after each dispensing cycle. A vision system is used as it provides flexibility and reliability to cater to a wide variety of RFID tags 7.

The RFID tag 7 is fed through the RFID separator 9 at a pre-determined distance depending on the pitch of the RFID tag 7. After dispensing, the position of the subsequent RFID tag 7 might vary depending on the accuracy of the pitching. The vision system of the RFID Positioning unit 5 will capture the position of the next RFID tag 7 and feedback the amount of difference to the RFID feeding station 23. The feeding motor (with the dancer units of the RFID inlay reel tensioning unit 4) will adjust the RFID inlay reel 1 by either moving the inlay reel 1 forward or backward to correct the position of the RFID tag 7 being inspected, so that a RFID tag 7 is always accurately positioned with respect to the RFID separator 9.

RFID Inspection Unit 6

The RFID inspection unit 6 utilises an appropriate RFID reader (not shown in any of the drawings) to read the RFID tag 7 before the dispensing cycle. The position of the RFID reader is adjustable to suit different RFID tag 7 sizes. The RFID tag 7 is considered good only if the RFID reader could read the RFID tag 7. The close proximity of the RFID tags 7 causes a conventional RFID reader to elicit readings from not just the defective RFID tag 7 but the adjacent RFID tags 7, as well.

The RFID inspection unit 6 must therefore be constructed to read only one RFID tag 7 at a time in order to detect a defective RFID tag 7 properly and accurately. The RFID inspection unit 6 is therefore mounted with a RFID electronic shield (also not shown in any of the drawings) which allows the RFID reader to read the RFID tag 7 immediately below the inspection unit 6. The RFID electronic shield also prevents any electronic signal sent out by the RFID inspection unit 6 to go beyond the RFID tag 7 being inspected, to the RFID tag 7 before or after the RFID tag 7 being inspected. In this way, the RFID reader can accurately read the RFID tag 7 it is supposed to read and not include the surrounding ones. The reading of the RFID tag 7 by the RFID inspection unit 6 is synchronized with the speed of the feeding motor all of which is controlled by the microcontroller.

The RFID shield can take the form of a RFID signal deflector which deflects the RFID signals from going sideways and outwards and instead direct all RFID signals downwards, directly onto the RFID tag 7 to be inspected.

RFID Separator 9

The RFID separator 9 is positioned just above the liner 10 and is normally at the extended position. In the dispensing process as shown in FIG. 2, the good RFID tag 7 will be separated from the RFID inlay reel 1 as the RFID inlay reel 1 passes over the extended separator 9 and which then get dispensed on to the liner 10. Once the RFID tag 7 is embedded onto the liner 10, the RFID label 8 is formed and the RFID label 8 is in turn fed to the Liner Buffer Station 15.

In operation, the RFID inspection and separation device remains in a separation mode wherein the good RFID tag 7 is separated and dispensed onto the liner 10. The RFID inspection and separation device goes into a non-separation mode whenever a defective RFID tag 7 is detected.

Winding Station 20

This winding station 20 utilizes an induction motor together with a dancer unit to wind up the empty RFID inlay reel 1 that feed out from the RFID Feeding Station 23.

Liner Unwinding Station 11

The incoming liner reel 1 will be loaded onto the Liner unwinding station 11. The reel 1 holding shaft is connected to a clutch and brake motor, which unwind the liner 10 to a dancer unit 22.

Punching Station 16

The Punching station 16 consists of a punching unit to punch a reference hole near to the edge of the liner 10. The punching unit is driven by a motor through a cam mechanism to achieve a high speed punching operation. The reference hole will be used to activate the dispensing process as well as to eliminate accumulative error on the feeding of the liner 10. Alternatively, the reference hole can also be replaced by printing coloured marks or magnetic marks.

Liner Feeding Station 14

The liner feeding station 14 consists of one set of feeding rollers driven by a servomotor to feed the liner 10 under the dispensing station. There are two sensors positioned accurately with respect to the punching station to sense the reference hole (made by the punching unit 16 at the punching station) on the liner 10. The first sensor is the dispensing sensor 12 to activate the dispensing of the RFID tag 7 and its position is dependent on the RFID position on the label 8. The second sensor is the pitch sensor 13 to check the feeding pitch of the liner 10 and its position is dependent on the label 8 length.

During feeding of the liner 10, once the dispensing sensor 12 senses the reference hole on the liner 10, the dispensing station will dispense to start the process of pasting a RFID tag 7 onto the liner 10 at the desired location. When the liner 10 is fed to the required pitch, the pitch sensor 13 will check the reference hole on the liner 10 before the punching station makes the reference holes on the liner 10.

Liner Buffer Station 15

The liner 10 pasted with non-defective RFID tag 7 will be fed to this Liner Buffer Station 15. Two limit sensors (not shown) are used to detect the buffer length of the liner 10. If the upper length limit is detected, an output signal will be given to the downstream machine to stop the operation. If the lower length limit is detected, the dispensing machine will stop the operation. The RFID labels 8 kept in the liner buffer station 15 are all non-defective RFID tags 7.

Microcontroller

In order to have the feeding of reels of RFID tags 7 (on the inlay reel 1) and liner synchronized, while each RFID tag 7 is detected and if found defective, not embedded onto the liner 10, information from each of the components in the detection and separation system and the RFID Conversion system are fed to a microcontroller (not shown in any of the drawings). In turn, the microcontroller sends out signals to each of the components so that the RFID tag 7 is positioned accurately before coming to the RFID dispensing station, and is positioned accurately at the RFID inspection unit 6 for detection of the RFID tag 7 immediately being checked for defect. The microcontroller also co-ordinates and synchronizes the entire production process including switching the detection and separation device from separation mode to non-separation mode and back.

The microcontroller is again an essential component of the entire process as it controls and co-ordinates the entire process of feeding the RFID tags 7, while feeding the liner 10, positioning the RFID tags 7 to be inspected and either separate the RFID tags 7 from the inlay reel 1 for embedding or discontinue the embedding if the RFID tag 7 is defective, all of which has to be carried out a relatively fast speed.

A description of the RFID Conversion system including a description of the detection and separation device is given below, with reference to FIGS. 1 and 2. The RFID Conversion system will have two reels mounted—a RFID inlay reel 1 of RFID tags 7 loaded onto the RFID Reel unwinding station 21 and a reel of liner 10 loaded onto the Liner Unwinding station 11. The entire process of the movements of RFID inlay reel 1 and liner 10 through all the components of the RFID Conversion system and through the device for Detection and Separation of defective RFID tags 7 is controlled by the microcontroller (not shown).
a. The incoming liner reel 10 will be loaded onto the liner Reel Unwinding station 11. The reel holding shaft is connected to a clutch and brake motor, which unwind the reel 10 to a dancer unit. The dancer unit provides a constant tension to the unwound liner 10.
b. The Punching Station 16 creates the reference hole on the liner 10. This reference hole is punched near to the edge of the liner 10. The punching unit is driven by a motor through a cam mechanism to achieve a high speed punching operation. The reference hole will be used to activate the dispensing process as well as to eliminate accumulative error on the feeding of the liner 10.
c. The Liner Feeding Station 14 feeds the liner 10 forward under the separator 9. The amount of feed depends on the length of the label 8.

The Liner Feeding Station 14 consists of one set of feeding rollers driven by a servomotor to feed the liner 10. There are two sensors positioned with respect to the punching station to accurately sense the reference hole on the liner 10. The first sensor is the dispensing sensor 12 to activate the dispensing of the RFID tag 7 and its position is dependent on the RFID position on the label 8. The second sensor is the pitch sensor 13 to check the feeding pitch of the liner 10 and its position is dependent on the label 8 length.
d. Once the dispensing sensor 12 detects the reference hole on the liner 10, the RFID Feeding Station 23 will feed the RFID inlay reel 1 through the RFID separator 9 to dispense the RFID tag 7 onto the liner 10 to form the RFID label 8. The amount of feed depends on the pitch of the RFID tag 7.
e. As the RFID tag 7 passes under and through the RFID Positioning Unit 5, the RFID Positioning unit 5 will check the position of the RFID tag 7. The RFID Feeding Station 23 will then correct the position of all RFID tags 7 accordingly so that only one RFID tag 7 passes through the RFID inspection unit 6 at a time.
f. The RFID inspection unit 6 will check the quality of the RFID tag 7 directly under it. Since the RFID inspection unit 6 uses radio frequency to detect whether the RFID tag 7 directly beneath it is working or not, the radio frequency signals are beamed out. To prevent the radio frequency signals from reading other RFID tags 7, an electronic shield (not shown) is mounted around the RFID inspection unit 6, so that radio frequency signals are beamed downwards only onto the RFID tag 7 to be tested.
g. If the RFID tag 7 is found defective, the inlay reel brakes 3 will clamp onto the inlay reel 1 to isolate the pulling force of the dancer unit 2 in the RFID Reel Tensioning Station 4. The RFID separator 9 will retract and the RFID Feeding Station 23 will feed the RFID inlay 1 forward so that the bad RFID tag 7 will pass the RFID separator 9 to the Winding Station 20. The inlay reel brakes 3 will then release the RFID inlay reel 1 and the RFID separator 9 will return to its separation mode by extending to its dispensing position.
h. Simultaneously from ‘e’, the liner 10 will continue to be fed by required pitch to its final position.
i. The pitch sensor 13 will check the reference hole on the liner 10. The Liner Feeding Station 14 will correct the position of the liner 10 accordingly before the operation can be repeated from ‘a’.

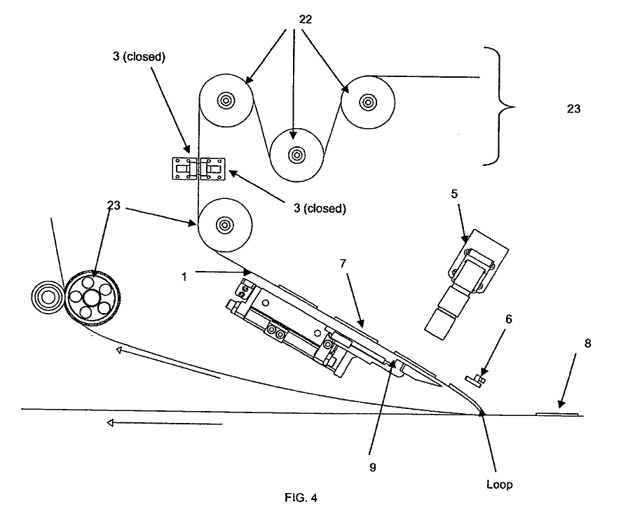

Basically RFID tags 7 rejection in the detection and separation device installed in the RFID Conversion System involves 3 steps, which are explained in more detail with reference to FIGS. 4, 5 and 6. The synchronization of all components within the detection and separation device is again carried out by the microcontroller.

FIG. 4 shows the first step of the inspection and separation process in which detecting a defective RFID tag 7. When the RFID inspection unit 6 detects a bad RFID tag 7, the microcontroller (not shown) will record down the position of this RFID tag 7 and continue the dispensing process. When the bad RFID tag 7 reaches the edge of RFID separator 9, the inlay reel brakes 3 of the RFID tensioning unit 4 will clamp onto the inlay reel 1 to isolate the pulling force of the dancer unit 2 in the RFID Reel Tensioning Station 4. The extended RFID separator 9 will then retract so that the RFID inlay 1 forms a free loop around the retracted RFID separator 9.

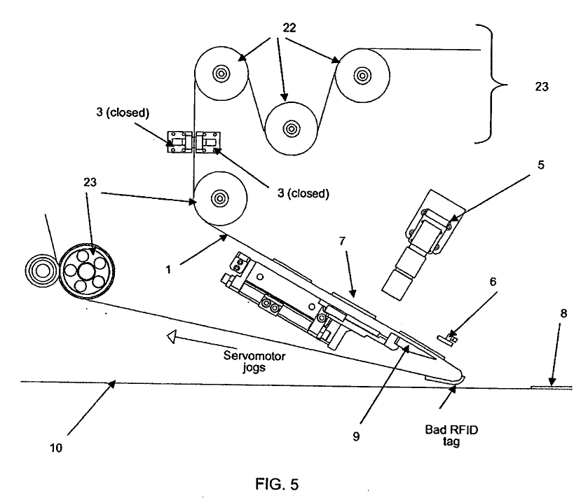

FIG. 5 shows the second step of the inspection and separation process wherein a defective RFID tag 7 is moved along back to the winding station 20, without going through the embedding process. The servomotor at RFID feeding station 23 jogs to feed the bad RFID tag 7 through the retracted RFID separator 9. The amount of feeding depends on the dimension of the RFID tags 7.

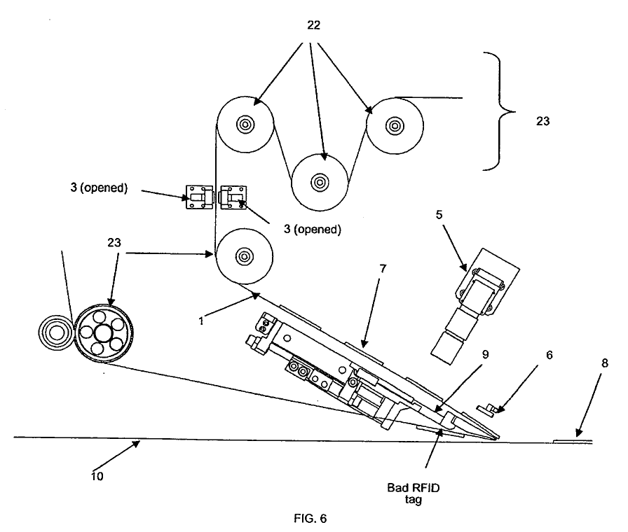

FIG. 6 shows the third step of inspection and separation process wherein the defective RFID tag 7 is returned to the winding station 20 upon rejection. The pair of inlay reel brakes 3 of the RFID Tensioning unit 4 will release the RFID inlay reel 1 and the retractable separator 9 will now extend (to its original extended state) to bring the subsequent RFID tag 7 back into dispensing position. The RFID Positioning unit 5 checks for correct RFID tag 7 position before the RFID dispensing operation resumes. As explained earlier, the entire process takes place at a high speed and the microcontroller ensures the RFID conversion process is carried out smoothly and possibly without operator intervention.

The liner 10 pasted with non-defective RFID tag 7 will be fed to the liner buffer station 15. Two limit sensors are used to detect the buffer length of the liner 10. If the upper length limit is detected, an output signal will be given to the downstream machine to stop the operation. If the lower length limit is detected, the dispensing machine will stop the operation.

The RFID label 8 kept in the liner buffer station 15 would now consists of all non-defective RFID labels 8, ready for shipment and for use. In this manner, all RFID labels 8 obtained by this process using the inspection and separation device are in good working order. The use of the inspection and separation device would ensure only non-defective RFID labels 8 are shipped out and used by end users, thereby reducing any further requirement for checking for damaged RFID labels 8 by end users. Much time and costs along the supply chain of RFID labels 8 is reduced by the use of the inspection and separation device.

As can be seen from the description given above, when RFID inspection unit 6 detects a bad RFID tag 7 on the RFID inlay 1, this particular RFID tag 7 will not be dispensed onto the liner 10. Instead it will remain on the RFID inlay reel 1 and eventually being fed back to the winding station 20. The winding station 20 would wind up the empty tape (including the defective RFID tags 7).

The RFID inspection unit 6 could also be a RFID sensor which checks whether the RFID is in working condition. The RFID inspection unit 6 could also be a RFID reader which reads test information contained therein and if the test information is read and verified, the RFID tag 7 would be taken as good.

The RFID reader (not shown) could be mounted with an electronic shield to direct the electronic signals of the RFID reader onto the RFID tag 7 immediately below the RFID inspection unit 6 so as to only read this RFID tag 7. Alternatively, the RFID reader could be mounted with a RFID signal deflector for the same purpose.

The pair of inlay reel brakes 3 of the RFID tensioning unit 4 could be a pair of clamping discs.

The pair of inlay reel brakes 3 of the RFID tensioning unit 4 could also be a pair of clamping cylinders.

The RFID Separation device 9 could be in the form of a retractable knife edge.

The RFID Separation device 9 could be in the form of a retractable blade.

In place of a reference hole being used to activate the dispensing process as well as to eliminate accumulative error on the feeding of the liner, the reference hole can also be a printing magnetic mark or a electronic dot.

While FIG. 1 illustrates an embodiment of the invention incorporated in a system for batch conversion of RFID tags into RFID labels, which is different from PCT/SG2004/000302, the RFID inspection unit and a separation device can also be installed in systems covered by PCT/SG2004/000302, with slight modification. A person skilled in the art would be able to adapt the RFID inspection and separation unit for installation on RFID conversion systems covered by PCT/SG2004/000302.

Although an embodiment of the invention have been described, it should be apparent, however, that various modifications, rearrangements, substitutions alterations and adaptations to those embodiments may occur to persons skilled in the art with the attainment of some or all of the advantages of the present invention. Accordingly, it should be clearly understood that the present invention is not intended to be limited by the particular features and structures hereinbefore described and depicted in the accompanying drawings. It is therefore intended to cover all such modifications, alterations and adaptations without departing from the scope and spirit of the present invention as defined by the appended claims.

### ADVANTAGEOUS EFFECTS OF THE INVENTION

The invention will ensure defective RIFD tags are not converted into RFID labels and shipped to end users. End users would only receive RFID labels in good working condition, ready for use in the applications.

The RFID detection and separation system can be used on any batch system use to convert RFID tags into RFID labels. It can also be adapted for use on batch conversion systems like those of PCT/SG2004/00302.

1. A RFID detection and separation device for a RFID Conversion system, said RFID Conversion system having a microcontroller, a liner unwinding station, a RFID reel unwinding station, a RFID feeding station, a liner feeding station, said microcontroller controlling the movement of an inlay reel of RFID tags from said RFID reel unwinding station into said RFID feeding station, said microcontroller also controlling the movement of a reel of liner mounted on said Liner Unwinding station, through said liner feeding station, for the separation of the RFID tags from said inlay reel for embedding onto the liner to produce RFID labels,
wherein in a separation mode, the RFID tag is inspected and if found good, the RFID tag is separated by the RFID detection and separation device and dispensed onto said liner to form said RFID label, and upon detection of a defective RFID tag, the RFID detection and separation device goes into a non separation mode, whereby the defective RFID tag passes the RFID detection and separation device without separation from said inlay reel.

2. A RFID detection and separation device for a RFID Conversion system, as claimed in claim 1, further comprising:
a RFID inspection unit; and
a RFID separator;
wherein said RFID tag is accurately positioned for inspection by said RFID inspection unit, and if said RFID tag is found defective, said RFID separator is retracted, allowing said defective RFID tag to remain on said inlay reel to return to said RFID Conversion System and if found good, said RFID separator is not retracted, thereby allowing said RFID tag to be embedded onto said liner, to form the RFID label.

3. A system comprising a RFID detection and separation device to detect and separate a defective RFID tag for a RFID Conversion system, the system having:
a RFID inspection unit;
a RFID separator; and
a RFID positioning unit;
wherein said RFID Positioning unit positions the RFID tag accurately with respect to the REID inspection unit and RFID separator in the detection and separation of a RFID tag for embedding onto a liner to produce a RFID label and in the detection and non-separation of a defective RFID tag from an RFID inlay reel if a defective RFID tag is found.

4. A system to detect and separate a defective RFID tag for a RFID Conversion system, as claimed in claim 3, the system further comprising:
a RFID Tensioning unit;
wherein said RFID Tensioning unit maintains a constant tension in said RFID inlay reel, to prevent reel breakage at high operation speed.

5. The system of claim 4, wherein said RFID tensioning Unit comprises a plurality of dancers and a pair of inlay reel brakes.

6. The system of claim 4, wherein said RFID Tensioning Unit comprises a servomotor with torque control.

7. The system of claim 4, wherein said RFID Tensioning Unit comprises a motor and clutch.

8. A system to detect and separate a defective RFID tag for a RFID Conversion system, as claimed in claim 5, wherein after a defective RFID tag is detected by said RFID inspection unit, and moves on over the RFID separator, said inlay reel brakes closes on said inlay reel to stop said inlay reel from moving and at the same time said RFID separator is retracted, so that the RFID tag does not separate from said inlay reel to be embedded onto said liner to return to a winding station and thereafter said pair of inlay reel brakes opens, said inlay reel moves forward with another RFID tag to be inspected.

9. The system of claim 3, wherein said RFID Positioning unit comprises a vision system which checks the position of the RFID tag to ensure it is accurately positioned with respect to said RFID separator so that the RFID tag can be read accurately by said RFID inspection unit after each dispensing cycle.

10. The system of claim 3, wherein said RFID Positioning unit comprises a vision system which checks and adjusts the position of the RFID tag on said inlay reel so that only the RFID tag directly below said RFID inspection unit is inspected.

11. The system of claim 3, wherein said RFID Positioning unit comprising an imaging system which takes an image of the RFID tag, checks and adjusts the position of the RFID tag on said inlay reel so that only the RFID tag directly below said RFID inspection unit is inspected.

12. The device of claim 2, wherein said RFID inspection unit comprises a RFID reader to read the RFID tag.

13. The device of claim 12 wherein said RFID reader is mounted with an electronic shield to direct electronic signals of the RFID reader onto the RFID tag immediately below said RFID inspection unit so as to only read said RFID tag immediately below said RFID inspection unit.

14. The device of claim 12 wherein said RFID reader is mounted with a RFID signal deflector to direct the electronic signals of the RFID reader onto the RFID tag immediately below said RFID inspection unit so as to only read said RFID tag immediately below said RFID inspection unit.

15. The device of claim 12 wherein said RFID reader is mounted with a RFID signal guide to guide the electronic signals of the RFID reader onto the RFID tag immediately below the RFID inspection unit so as to only read said RFID tag immediately below said RFID inspection unit.

16. The device of claim 2, wherein said RFID separator 9 is positioned above said liner and in a separation mode is in an extended state so that as said RFID inlay reel with the RFID tags on it goes over said RFID separator, said RFID separator separates the RFID tags from said RFID inlay reel allowing the RFID tags to be dispensed onto said liner, thereby embedding the RFID tag onto said liner, to form RFID labels.

17. The device of claim 2, wherein said RFID separator is positioned above said liner and upon detection of a defective RFID tag, said RFID detection and separation device goes into a non-separation mode whereby said microcontroller sends a signal to said RFID separator, causing it to retract and as said RFID separator is no longer in an extended state, said RFID inlay reel with the defective RFID tag on it round goes over said retracted RFID separator, said inlay reel forming a free loop, so that the defective RFID tag would not be dispensed onto said liner, and instead is returned to a winding station.

18. The device of claim 2, wherein said RFID separator has an edge, and wherein upon detection by said RFID inspection unit of a defective RFID tag, the RFID detection and separation device goes into a non-separation mode, whereby the position of the defective RFID tag is recorded by said microcontroller, which continues to move said inlay reel with the defective RFID tag along until it reaches said edge of said RFID separator, said microcontroller sends a signal to inlay reel brakes so that it closes on said inlay reel and at the same time, the RFID separator retracts, and said RFID inlay forms a free loop around the retracted RFID separator, so that the RFID tag on said inlay reel is not dispensed onto said liner and instead returns to a winding station.

19. The device of claim 2, wherein said RFID separator is positioned above said liner so that after the defective RFID tag has been detected by said RFID inspection unit, and after the defective RFID tag has gone past the retracted RFID separator, the RFID detection and separation device goes back to its separation mode whereby said microcontroller sends a signal to inlay reel brakes to release said RFID inlay, and said RFID separator moves back to its normal extended position, and the RFID tags are moved forward through the RFID detection and separation device to continue the RFID conversion process.

20. The device of claim 16, wherein said RFID separator comprises a retractable knife edge.

21. The device of claims 16, wherein said RFID separator comprises a retractable blade.

22. The system of claim 5, wherein said pair of inlay reel brakes is in an opened position, when the RFID detection and separation device is in a separation mode, such that the RFID tags on said inlay reel are moved through said RFID inspection unit, and when a good RFID tag is detected by said RFID inspection unit, said inlay reel brakes remain open so that said inlay reel with the good RFID tag moves past the RFID separator, to be dispensed onto said liner, to produce RFID labels.

23. The system of claim 5, wherein said pair of inlay reel brakes is in an opened position, when the RFID tags on said inlay reel are moved through said RFID inspection unit, and when a defective RFID tag is detected by said RFID inspection unit, the RFID detection and separation device goes into a non-separation mode, whereby said microcontroller closes said pair of inlay reel brakes together to stop movement of said inlay reel and at the same time, said microcontroller retracts the RFID separator, causing said RFID inlay to form a free loop around the retracted RFID separator, so that the RFID tag on said inlay reel is not dispensed onto said liner and instead returns to a winding station.

24. The system of claim 5, wherein said pair of inlay reel brakes, after the defective RFID tag has gone past the retracted RFID separator, to a winding station, the RFID detection and separation device goes back to its separation mode, whereby said microcontroller sends a signal to said inlay reel brakes to open, said RFID inlay is then released, causing the next RFID tag on said inlay reel to move through said RFID inspection unit, and the RFID separator moves back to its normal extended position, so that the RFID conversion process continues.

25. The system of claim 5, wherein said pair of inlay reel brakes of said RFID Tensioning Unit comprises a pair of clamping cylinders.

26. The system of claim 5, wherein said pair of inlay reel brakes of said RFID Tensioning Unit comprises a pair of clamping discs.

27. A method to detect and separate defective RFID tags comprising the steps of:
providing a RFID detection and separation device for a RFID Conversion system, said RFID Conversion system having a microcontroller, a liner unwinding station, a RFID reel unwinding station, a RFID feeding station, a liner feeding station, an RFID tensioning unit having a pair of inlay reel brakes, an RFID separator, and a RFID positioning unit, said microcontroller controlling the movement of an inlay reel of RFID tags from the RFID reel unwinding station into the RFID feeding station, said microcontroller also controlling the movement of a reel of liner mounted on said Liner Unwinding station, through said liner feeding station, for the separation of the RFID tags from said inlay reel for embedding onto the liner to produce RFID labels,
Inspecting a RFID tag as it goes under said RFID Positioning Unit;
sending an electronic signal from a RFID reader to read the RFID tag;
identifying a defective RFID tag and sending a signal to said microcontroller, which continues to move said RFID inlay reel containing said defective RFID tag; until it reaches said RFID separator,
sending a signal to said pair of inlay reel brakes of said RFID Tensioning unit to stop movement of said RFID inlay reel, when the defective RFID tag goes over said RFID separator 9,
retracting said RFID separator so it is no longer in an extended state,
allowing said RFID inlay reel with the defective RFID tag 7 on it to go over the retracted RFID separator, said RFID inlay reel forming a free loop, so that the defective RFID tag would not be dispensed onto said liner, and instead returns to a winding station; sending a signal to said pair of inlay reel brakes of said RFID Tensioning unit to release said RFID inlay reel,
extending said RFID separator so that it moves back to its normal extended position,
so that the next RFID tag is moved forward to the inspection unit to be inspected,
and thereby continuing the RFID Batch conversion process until said microcontroller detects either the end of said RFID inlay reel or said liner is reached and after which the RFID Batch Conversion process is stopped.

28. The method to detect and separate defective RFID tags as claimed in claim 27, whereby the steps of Inspecting a RFID tag as it goes under said RFID Positioning unit, detecting a defective RFID tag, moving the RFID tag past said RFID separator which is then retracted, applying said inlay reel brakes of said RFID Tensioning Unit on said inlay reel to stop momentarily the movement of said inlay reel so that said inlay reel forms a free loop around said RFID separator, releasing said inlay reel brakes to move the next RFID tag to be inspected, all these steps being controlled by said microcontroller.

29. The device of claim 17, wherein said RFID separator comprises a retractable knife edge.

30. The device of claim 18, wherein said RFID separator comprises a retractable knife edge.

31. The device of claim 19, wherein said RFID separator comprises a retractable knife edge.

32. The device of claim 17, wherein said RFID separator comprises a retractable blade.

33. The device of claim 18, wherein said RFID separator comprises a retractable blade.

34. The device of claim 19, wherein said RFID separator comprises a retractable blade.
